(19) United States
(12) Patent Application Publication
(10) Pub. No.: US 2012/0188023 A1
(43) Pub. Date: Jul. 26, 2012

(54) Optimal Leg Design for MEMS Resonator

(75) Inventors: Xavier Rottenberg, Kessel-Io (BE); Roelof Jansen, Leuven (BE); Steve Stoffels, Heverlee (BE); Hendrikus Tilmans, Maasmechelen (BE)

(73) Assignee: IMEC, Leuven (BE)

(21) Appl. No.: 13/150,442

(22) Filed: Jun. 1, 2011

Related U.S. Application Data
(60) Provisional application No. 61/434,891, filed on Jan. 21, 2011.

(51) Int. Cl. H03B 5/30

(52) U.S. Cl. 331/156

(57) ABSTRACT

A microelectromechanical (MEMS) resonator is disclosed that comprises a substrate and a resonator body suspended above the substrate by means of clamped-clamped beams, where each beam comprises two support legs with a common connection to the resonator body, and the resonator body is configured to resonate at an operating frequency. The MEMS resonator further comprises an excitation component configured to excite the resonator body to resonate at the operating frequency, where each beam is further configured to oscillate in a flexural mode at a flexural wavelength as a result of resonating at the operating frequency, and each leg is acoustically long with respect to the flexural wavelength.

### CROSS-REFERENCE TO RELATED APPLICATIONS

This application is a non-provisional of U.S. Provisional Patent Application Ser. No. 61/434,891 filed Jan. 21, 2011, the contents of which are hereby incorporated by reference.

### BACKGROUND

The present disclosure relates to a microelectromechanical or nanoelectromechanical resonator structure with optimised support anchoring.

Microelectromechanical (MEM) or nanoelectromechanical (NEM) resonators are regarded as a promising choice for timing references to replace for example quartz crystal oscillators in electronic circuits as disclosed by W.-T., Hsu, J. R. Clark, et al., in <<Mechanically temperature-compensated flexural-mode micromechanical resonators”, Technical Digest International Electron Devices Meeting 2000 (IEDM2000), pp. 399-402, hereby incorporated by reference in its entirety.

One of the main drawbacks of these MEMS resonators, however, is frequency stability which can be adversely influenced by temperature drifts and aging. As a result, temperature stability is of paramount importance to ensure a precise resonant frequency on a repeatable and predictable basis. The temperature dependence of the resonance frequency of typical mechanical resonators is typically dominated by the temperature dependence of the Young's modulus of the constitutive material of the resonator.

For Si(Ge)-based MEM resonators, which are quickly gaining traction in microelectronics, this temperature dependence is unfortunately too large (much larger than for quartz crystal resonators) to allow the passive implementation of these resonators in, for example, handheld applications where the temperature specifications range for example from −40° C. to 85° C.

Another important design aspect of an MEMS resonator that needs to be taken into account is the minimization of the acoustic energy loss to the substrate. This mainly depends on the design of the support beams that anchor the MEMS resonator body to the substrate.

Electro-mechanical stability or rigidity of the MEMS resonator in the direction of the vibration also needs to be considered and is highly dependent on the design of the support anchoring beams that are used to connect the MEMS resonator body to the substrate.

### SUMMARY

Disclosed is an MEMS resonator with improved thermal resistance towards the substrate above which it is suspended. The improved thermal resistance does not adversely affecting the electro-mechanical stability of the MEMS resonator.

According to one embodiment, the MEMS resonator comprises a substrate and a resonator body suspended above the substrate by means of clamped-clamped beams, each beam comprising two support legs with a common connection to the resonator body. The resonator body is adapted for resonating at an operating frequency (fᵣₑₛ). The MEMS resonator further includes an excitation component for exciting the resonator body into a vibration at the operating frequency (fᵣₑₛ).

According to some embodiments, each beam is adapted for oscillating in a flexural mode at a given flexural wavelength as a result of the vibration of the resonator body at the operating frequency (fᵣₑₛ). This means that the properties of the beam are selected such that the beam is made to oscillate in the flexural mode (i.e., to exhibit a low stiffness for this oscillation) as a result of the targeted vibration of the resonator body. It has been found that the ability of the beam to oscillate in the flexural mode can enhance or at least maintain the electro-mechanical stability of the resonator while an understanding of the flexural mode can be used to optimise the beam design for other parameters.

According to some embodiments, each leg is acoustically long with respect to said flexural wavelength of the beam vibration. For example, each leg may have a relatively long length with respect to prior art devices, which enhances the thermal insulation of the resonator body. As a result, the resonator of the disclosure can be heated to an operating temperature to keep the operating frequency substantially stable, without significant heat loss towards the substrate. The common central connection may be selected or designed to have a minimum length in view of electro-mechanical stabitily. The minimum length is determined by the design parameters and fabrication process.

In preferred embodiments, each leg has a length (L_{Tsup,opt}) equal to a predetermined multiple of said flexural wavelength divided by two, plus a predetermined offset. The predetermined multiple may be selected in view of optimizing thermal resistance of the leg. Further, the predetermined offset may be selected in view of optimizing a quality factor of the resonator. By selecting one of these lengths for the support legs, the impedance at the connection point of the resonator and the impedance at the anchors are matched. As a consequence, the loss of energy to the substrate via the anchors can be minimized and a resonator device with an optimized Q-factor can be provided.

In some embodiments, the predetermined offset is substantially equal to half the length (L_{cl-cl, 1}) of a clamped-clamped beam with first flexural resonance frequency equal to the operating frequency (fᵣₑₛ). It has been found that the Q-factor is a periodic function of the support leg length of the resonator and that this predetermined offset substantially corresponds to the maxima of the periodic function.

In some embodiments, the resonator body is adapted for resonating in a breathing mode. The breathing mode may have a symmetry axis. During the breathing mode, displacement may be minimal and the common connections of the clamped-clamped beams may be located at the symmetry axis. As a result, the beams may be connected to the resonator body at points of minimal displacement, which can enhance the electro-mechanical stability of the resonator.

The high levels of electro-mechanical stability which can be achieved according to the disclosure further allows large voltages to be applied without the danger of pull-in, thus achieving lower motional impedance of the MEMS resonator which can, in turn, lead to easier integration.

In some embodiments, the clamped-clamped beams are T-shaped and centrally connected to the resonator body. In alternative embodiments, the clamped-clamped beams can also be, for example, angled beams.

In some embodiments, the clamped-clamped beams have a rigid direction, and the excitation component is configured to excite the resonator body in the rigid direction of the beams. For example, in the case of T-shaped beams, the rigid direction may be the longitudinal direction of the support legs and the beams may have a low stiffness in any direction orthogonal thereto.

In some embodiments, at least one of the beams forms a heating resistance for heating the resonator through Joules heating. A stable temperature can thus be achieved by controlling the amount of current passing through the clamped-clamped beams. In addition, by using the acoustically long legs, the heat transfer from the resonator to carrier wafer and from carrier wafer to the resonator can be minimized. In this way the resonator can be partially shielded from transient temperature changes of the carrier wafer since the heat generated in the clamped-clamped beams or support is preserved to the current location.

Several embodiments of the MEMS resonator of the disclosure as described above can offer a precise resonant frequency, electro-mechanical stability and a high Q-factor. The disclosure or its embodiments offer an improved MEMS resonator device, with improved frequency stability control, temperature insulation, electro-mechanical stability and high Q-factor.

### BRIEF DESCRIPTION OF THE DRAWINGS

The disclosure will be further elucidated by means of the following description and the appended drawings.

FIG. 1 shows a general overview of an example MEMS resonator, in accordance with an embodiment.

FIG. 2 shows a top view of a bar-type bulk acoustic wave (BAW) resonator with “acoustically long” T supports.

FIG. 3 shows a scanning electron microscope image of a SiGe bar-type BAW resonator with acoustically long T-type supports.

FIG. 4 shows example values for example design parameters, in accordance with an embodiment.

FIG. 5 shows a representation of an example quarter-wave matching transformer.

FIG. 6 shows a Smith chart representation of an example short-to-open transformation through use of a (2i+1) λ/4 transmission line section.

FIG. 7 shows a scanning electron microscope image of a resonator with T-type support, in accordance with an embodiment.

FIG. 8 shows example results from FEM simulations.

FIG. 9 shows a perspective view of an example MEMS resonator with Joules heating via the supports and temperature measurement by means of a resistance on top of the resonator body, in accordance with an embodiment.

FIGS. 10A-C show example displacement of an oscillating MEMS resonator, in accordance with an embodiment.

### DETAILED DESCRIPTION

The present disclosure will be described with respect to particular embodiments and with reference to certain drawings but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the disclosure.

Furthermore, the terms first, second, third and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the disclosure described herein can operate in other orientations than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present disclosure, the only relevant components of the device are A and B.

As used herein, the term resonator encompasses all structures having or capable of having a desired mechanical or electro-mechanical vibration. In the examples that follow, a bar resonator is used. The application is not, however, limited to resonant beams having rectangular cross sections; other cross sections are possible as well.

Below, embodiments of MEMS resonator devices are described with optimal support anchoring for providing frequency and electro-mechanical stability and high Q-factor. However, the disclosure is not limited to a specific type of a MEMS resonator device, and can be used in its entity to any resonating structure.

FIG. 1 shows a general overview of an example MEMS resonator, in accordance with an embodiment. As shown, the MEMS resonator comprises a main resonator body 1. The main resonator body may take any shape including, for example, rectangular, square, circular, parallelepiped, and cubic shapes. Other shapes are possible as well.

The MEMS resonator further comprises at least one means of actuation 6, 7. Each means of actuation may be, for example, an electrode or a magnetic means of actuation. As shown, each means of actuation is placed in close proximity to the main resonator body 1 and at least one T-shaped support 4 used to anchor the main resonator body 1 to the substrate. In particular, each means of actuation may be at a particular transduction gap 8, 9, to the main resonator body 1 and the T-shaped support 4.

The T-shaped support or T-support further comprises a clamped-clamped beam or support comprising two legs 41, 42 attached by means of anchors 2, 3 to the substrate. Further, the two legs 41, 42 are attached by means of a common and, in some cases, central connection 5 to the main resonator body 1.

The MEMS resonator device or structure is configured to resonate at least in a predetermined mode, such as a breathing mode. The main resonator body resonates at a resonance frequency (fᵣₑₛ) related to its natural response. The length of the clamped-clamped beams is in view of the flexural wavelength (that is, the type of wavelength dependent on the stress component most important to support) in order to provide frequency stability and a high Q factor. The T-shaped design utilizing a rigid clamped-clamped support provides electro-mechanical stability in the direction of actuation. In particular, the length (L_{Tsup}) of each leg 41, 42 of the beam is chosen as a multiple of half the flexural wavelength plus an offset term.

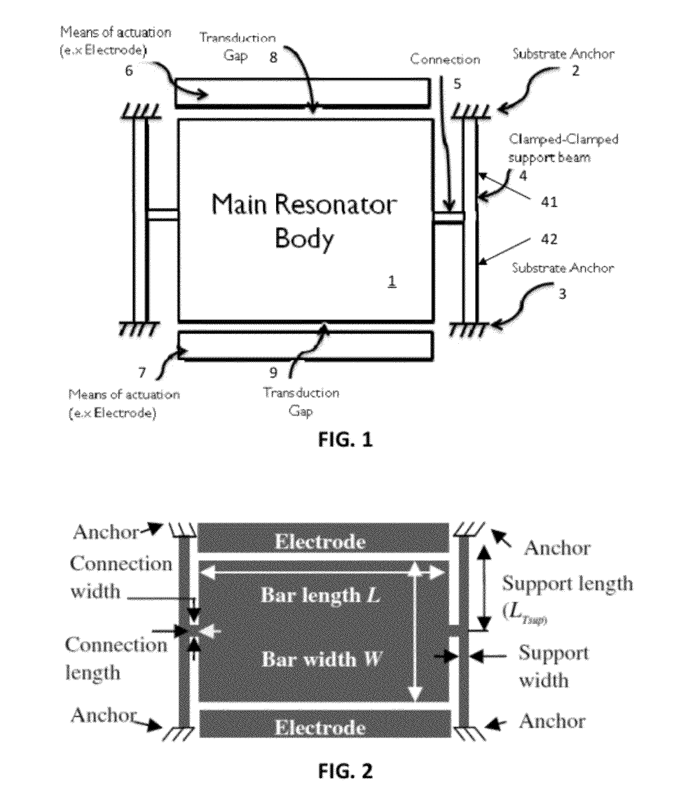

The present disclosure is further exemplified by means of a bar-type bulk acoustic (BAW) resonator device configured to vibrate along its width in an extensional mode (e.g., a breathing mode). FIG. 2 shows a top view of a bar-type bulk acoustic wave (BAW) resonator with “acoustically long” T supports.

As shown, the BAW resonator comprises a bar, which acts as the main resonator body of the resonator, and two means of actuation (e.g., electrodes) on either side of the main resonator body (the bar).

The bar and electrodes have been designed as right parallelepipeds suspended in free space by means of supports, which anchor the MEMS resonator to the substrate. The anchoring supports are T-shaped, as shown in FIG. 2. The T-shaped supports further comprise a clamped-clamped support beam placed parallel to the resonator and connected to the main resonator body at the symmetry line with a short, narrow connection.

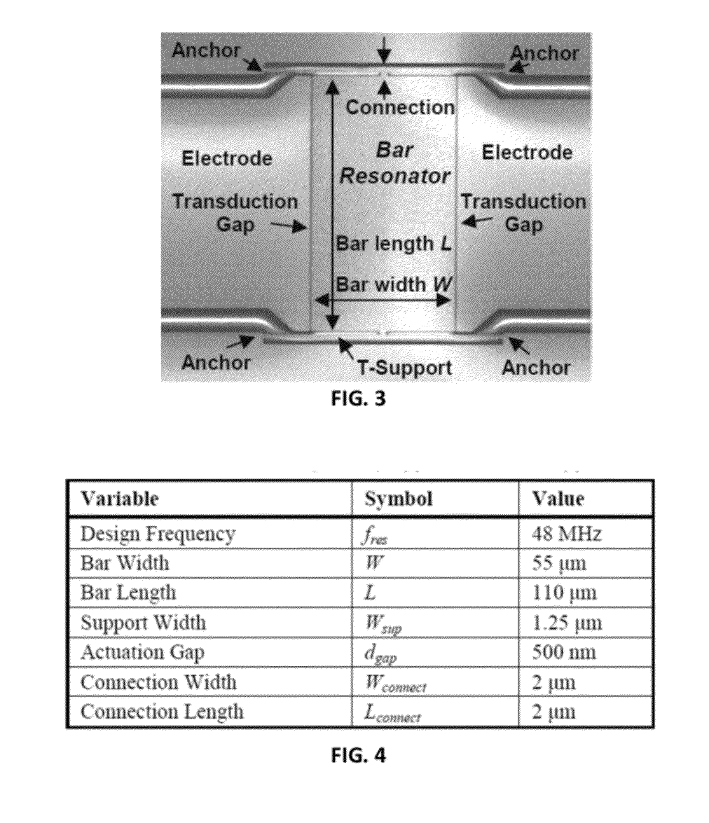

FIG. 3 shows a scanning electron microscope (SEM) image of a SiGe bar-type BAW resonator with acoustically long T-type supports. The bar vibrates along its width in an extensional mode. A bar targeting a resonance frequency fᵣₑₛ is designed with a bar width W close to λ_{long}/2, where λ_{long} is the acoustic longitudinal wavelength at fᵣₑₛ. The resonance frequency, for the first width extensional mode, is approximately given by:

$${f}_{res} \approx \frac{1}{2 W} \sqrt{\frac{E}{ρ}} \qquad ( 1 )$$

where E and ρ denote the Young's modulus and specific mass of the resonator material, respectively. According to equation (1), an E of 120 GPa, a ρ of 4577 kg/m3, and a W of 55 μm results in a resonance frequency of 48 MHz. FIG. 4 shows example values for example design parameters, in accordance with an embodiment.

Returning to FIG. 3, the bar resonator is electro-statically actuated via two electrodes separated from the resonator by transduction gaps (500 nm in this work). The device can either be used in a two-port configuration using one electrode to excite and the other to detect the signal, or in a one-port configuration in which the device is excited and detected by the same electrodes (connected in parallel).

The T-shaped support (such as that shown in FIG. 2) comprises a support placed parallel to the side of the resonator connecting to the resonator at the symmetry line with a short, narrow connection 5.

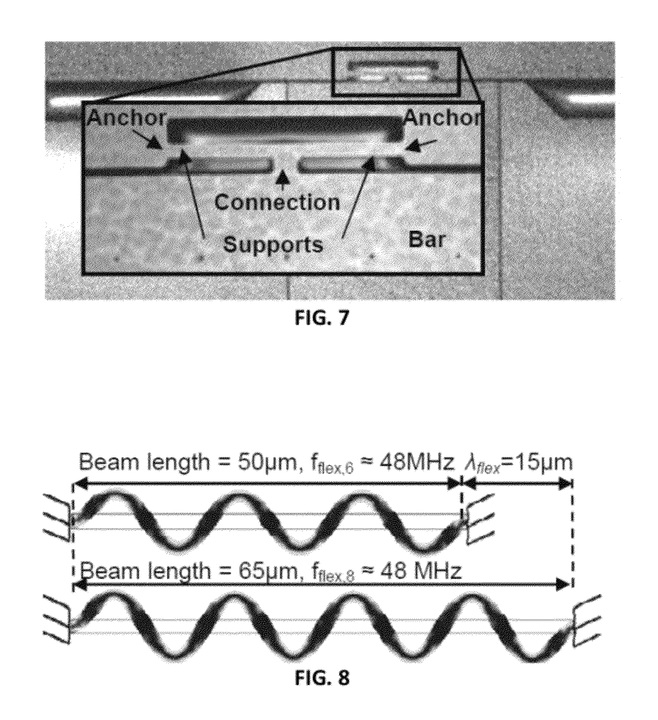

FIG. 7 shows an SEM image of a resonator with T-type support, in accordance with an embodiment. To determine the optimal length of the support, one may refer to the analogy with the quarter-wave (λ/4) transformer concept known from radiofrequency (RF) theory.

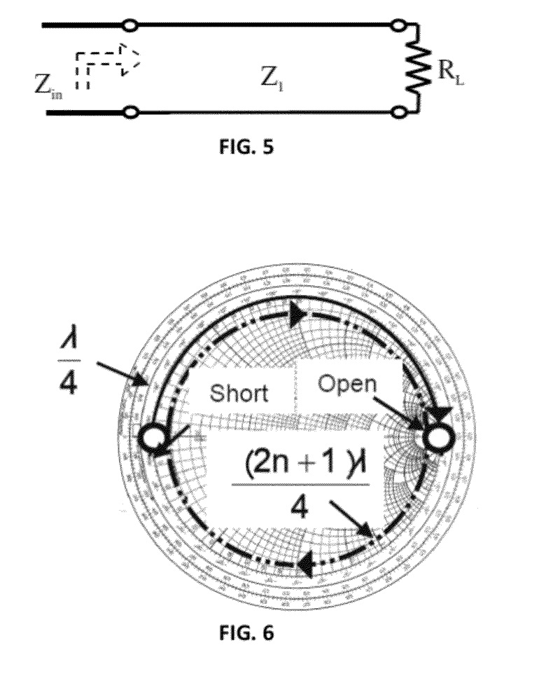

FIG. 5 shows a representation of an example quarter-wave matching transformer. The impedance transformation from a transmission line with length “λ/4” is given by:

$${Z}_{i n} = \frac{{Z}_{1}^{2}}{{R}_{L}} \qquad ( 2 )$$

where the impedance Z₁, is the (acoustic) impedance seen by the resonator looking into the support, Z₁ is the characteristic acoustic impedance of the support beam (modeled as an acoustic transmission line),m and R_{L} is the acoustic impedance seen at the anchor. Since the anchoring provides an acoustic energy path to the substrate we can see R_{L} as a type of acoustic short which absorbs all acoustic energy. If R_{L}=0, the quarter wave transforms the impedance seen at the resonator to an open, effectively confining the acoustic energy to the resonant body. This is demonstrated in FIG. 6, which shows a Smith chart representation of an example short-to-open transformation through use of a (2i+1) λ/4 transmission line section.

At first sight it seems that the impedance Z₁ is unimportant. However, since R_{L} is not a perfect short we need to maximize Z₁, by choosing the support width to be as narrow as possible in order to maximize the acoustic impedance Z₁. The λ/4 transformer technique described can again be applied for the T-type support to obtain an optimum support length L_{Tsup,opt} to minimize energy losses to the anchors, with L_{Tsup,opt} given by:

$${L}_{Tsup , opt} \approx \frac{2 i {λ}_{flex}}{4} + \frac{{L}_{cl \text{-} cl , 1}}{2} , i = 0 , 1 , 2 , 3 … \qquad ( 3 )$$

where the flexural wavelength λ_{flex} (see equation (5) below) is used since the most important stress component is now perpendicular to the support.

Because T-shaped support anchoring further allows more flexibility in all other directions, the T-shaped support legs can be designed with dimensions that enable alternative resonant modes, such as elongating, out of plane, and side to side or tilting. Accordingly, for a fixed support length, a resonant mode can be selected, thereby obtaining an MEMS resonator having a high (optimal) Q factor.

L_{cl-cl,1} is the length of a clamped-clamped beam with first flexural

$${L}_{cl \text{-} cl , 1} \approx \sqrt{\frac{1.028 {W}_{sup} \sqrt{E / ρ }}{{f}_{res}}} \qquad ( 4 )$$

For a given clamped-clamped beam, the flexural wavelength λ_{flex} is given by:

$${λ}_{flex} = {lim}_{n -> ∞} ( {L}_{( n + 2 )} - {L}_{n } ) \qquad ( 5 )$$

where L₍ₙ₊₂₎ and Lₙ are the lengths of beams with respectively (n+2)th and nth flexural harmonics occurring at the frequency fᵣₑₛ. The limit of n is taken so as to minimize the effect of the (clamped edge) anchoring.

FIG. 8 shows example results from FEM simulations. In particular, FIG. 8 shows how equation (4) is used together with FEM results to obtain λ_{flex}=15 μm for the design parameters in Table 1. We can compute λ_{flex} with equation (5), after which L_{Tsup,opt} is obtained from equation (3).

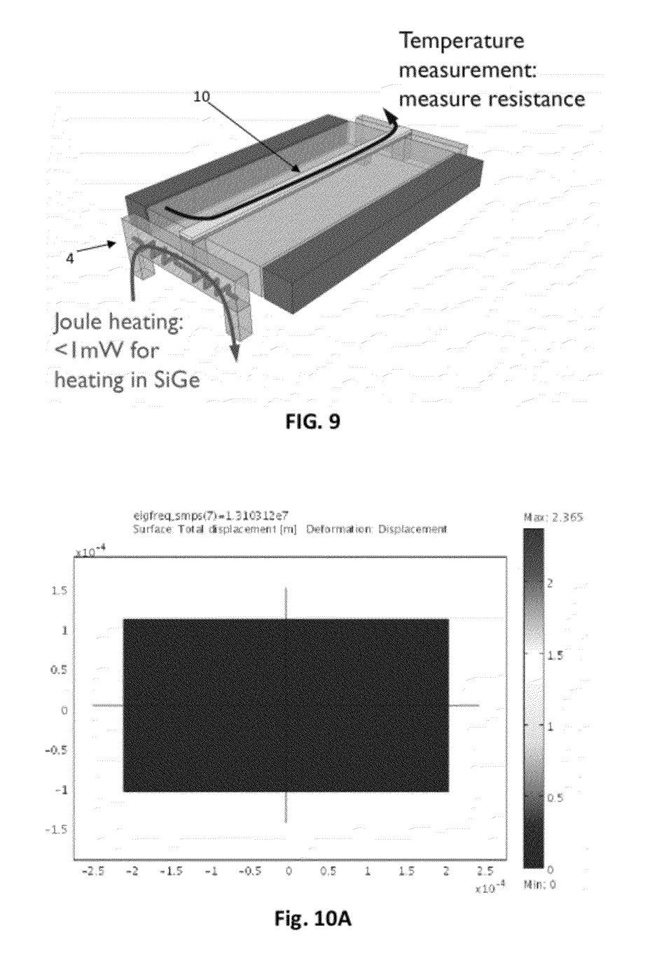

FIG. 9 shows a perspective view of an example MEMS resonator with Joules heating via the supports and temperature measurement by means of a resistance on top of the resonator body, in accordance with an embodiment. In the embodiment shown in FIG. 9, the T-shaped support 4 is used for heating the MEMS resonator main body to the operating temperature. Current is supplied to the T-shaped support for achieving Joules heating. In order to control the current, the temperature of the main body is measured by means of a resistance 10 on top of the resonator body. Using this principle in combination with the acoustically long leg design, power consumption for heating can be reduced to below 1 mW.

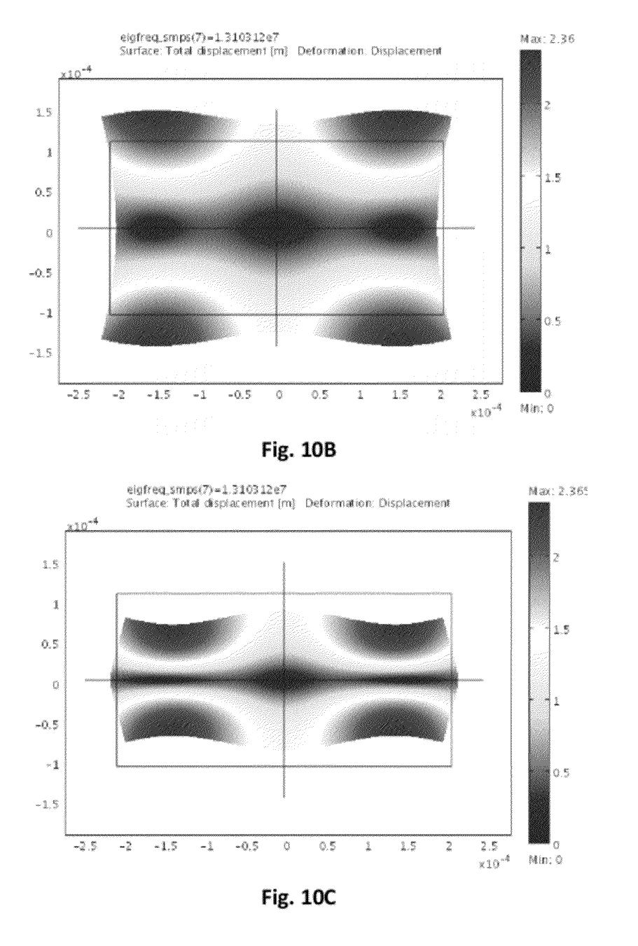

FIGS. 10A-C show example displacement of an oscillating MEMS resonator, in accordance with an embodiment. In some embodiments, the resonator may oscillate in a breathing mode in which the body expands and contracts. FIG. 10A shows the main body in its original, flat shape having no displacement. FIG. 10B shows the displacement at the point of maximum expansion of the oscillation of the main body. As shown, there is substantially no displacement at the longitudinal (central) axis of the body, while there is maximal displacement along the longitudinal edges of the body. FIG. 10C shows the displacement at the point of maximum contraction of the oscillation of the main body. As shown, there is likewise substantially no displacement at the longitudinal axis of the body, and maximal displacement along the longitudinal edges of the body. This shows that this longitudinal axis is the best place to connect the supports for this oscillator in this breathing mode.

1. A microelectromechanical (MEMS) resonator comprising:
a substrate;
a resonator body suspended above the substrate by means of clamped-clamped beams, wherein:
each beam comprises two support legs with a common connection to the resonator body, and
the resonator body is configured to resonate at an operating frequency; and
an excitation component configured to excite the resonator body to resonate at the operating frequency, wherein:
each beam is further configured to oscillate in a flexural mode at a flexural wavelength as a result of resonating at the operating frequency, and
each leg is acoustically long with respect to the flexural wavelength.

2. The MEMS resonator of claim 1, wherein each leg has a length equal to a predetermined multiple of the flexural wavelength divided by two, plus a predetermined offset.

3. The MEMS resonator of claim 2, wherein the predetermined multiple is based at least in part on optimizing thermal resistance of the leg and a quality factor of the resonator.

4. The MEMS resonator of claim 2, wherein the predetermined offset is based at least in part on optimizing a quality factor of the resonator.

5. The MEMS resonator of claim 2, wherein the predetermined offset is substantially equal to half the length of a clamped-clamped beam with a first flexural wavelength substantially equal to the operating frequency.

6. The MEMS resonator of claim 5, wherein the length of the clamped-clamped beam is approximated by
$${L}_{cl \text{-} cl , 1} \approx \sqrt{\frac{1.028 {W}_{sup} \sqrt{E / ρ}}{{f}_{res}}}$$
where Wₛᵤₚ is the width of the support legs, E is the Young's modulus of the resonator, and ρ is the specific mass of a material of the resonator.

7. The MEMS resonator of claim 1, wherein the resonator body is configured to resonate in a breathing mode.

8. The MEMS resonator of claim 7, wherein:
the resonator comprises a symmetry axis, and
the resonator body has minimal displacement along the symmetry axis while resonating in the breathing mode.

9. The MEMS resonator of claim 8, wherein the common connections of the clamped-clamped beams are located along the symmetry axis.

10. The MEMS resonator of claim 1, wherein the clamped-clamped beams are T-shaped and centrally connected to the resonator body.

11. The MEMS resonator of claim 1, wherein the clamped-clamped beams are angled.

12. The MEMS resonator of claim 1, wherein the clamped-clamped beams have a rigid direction.

13. The MEMS resonator of claim 12, wherein the excitation component is configured to excite the resonator body in the rigid direction.

14. The MEMS resonator of claim 1, wherein at least one of the beams forms a heating resistance for heating the resonator through Joules heating.

15. The MEMS resonator of claim 1, further comprising a resistor on the resonator body.

16. A bar-type acoustic wave (BAW) resonator comprising:
a substrate;
a resonator body suspended above the substrate by means of clamped-clamped beams, wherein:
each beam comprises two support legs with a common connection to the resonator body, and
the resonator body is configured to resonate at an operating frequency; and
an excitation component configured to excite the resonator body to resonate at the operating frequency, wherein:
each beam is further configured to oscillate in a flexural mode at a flexural wavelength as a result of resonating at the operating frequency, and
each leg is acoustically long with respect to the flexural wavelength.

17. The BAW resonator of claim 16, wherein each leg has a length equal to a predetermined multiple of the flexural wavelength divided by two, plus a predetermined offset.

18. The BAW resonator of claim 17, wherein the predetermined multiple is based at least in part on optimizing thermal resistance of the leg and a quality factor of the resonator.

19. The BAW resonator of claim 17, wherein the predetermined offset is based at least in part on optimizing a quality factor of the resonator.

20. The BAW resonator of claim 17, wherein the predetermined offset is substantially equal to half the length of a clamped-clamped beam with a first flexural wavelength substantially equal to the operating frequency.
